(19) United States
(12) Patent Application Publication
(10) Pub. No.: US 2024/0196702 A1
(43) Pub. Date: Jun. 13, 2024

(54) DISPLAY DEVICE

(71) Applicant: LG Display Co., Ltd., Seoul (KR)

(72) Inventor: Byeongjo MIN, Paju-si (KR)

(73) Assignee: LG Display Co., Ltd., Seoul (KR)

(21) Appl. No.: 18/234,758

(22) Filed: Aug. 16, 2023

(30) Foreign Application Priority Data
Dec. 8, 2022 (KR) 10-2022-0170363

(51) Int. Cl. H10K 59/80

(52) U.S. Cl. CPC H10K 59/873; H10K 59/8792

(57) ABSTRACT

A display device can include a display panel, a cover member positioned on the display panel, a back cover positioned on a backside of the display panel, and a scaling member positioned between the back cover and the cover member. The sealing member can include a molding member or foam member.

### CROSS REFERENCE TO RELATED APPLICATION

The present application claims priority to Korean Patent Application No. 10-2022-0170363, filed Dec. 8, 2022 in the Republic of Korea, the entire contents of which are hereby expressly incorporated by reference into the present application.

### BACKGROUND OF THE DISCLOSURE

### Field

The present invention relates to a display device.

### Discussion of the Related Art

Generally, when assembling a cover member (or cover window) and a back cover beneath a display panel, it is common to securely fix and seal them using a double-sided tape or resin.

However, in this case, when repairing at least one component or part between the cover member and the back cover, it is needed to separate the mutually attached cover member and back cover, which can pose a risk of physical damage to the cover member and/or the back cover.

### SUMMARY OF THE DISCLOSURE

The present invention has been conceived to solve or address the above limitation and other limitations associated with the related art.

It is an object of the present invention to provide a display device capable of preventing or minimizing physical damage to the cover member and/or the back cover in advance.

The objects of the present invention are not limited to the aforesaid, and other objects not described herein with be clearly understood by those skilled in the art from the descriptions below.

In order to accomplish the above objects, a display device according to an embodiment of the present invention includes a display panel, a cover member positioned on the display panel, a back cover positioned on the underside of the display panel, and a sealing member positioned between the back cover and the cover member, wherein the sealing member includes a molding member or foam member.

In order to accomplish the above objects, a display device according to an aspect of the present invention includes a display panel, a cover member positioned on the display panel, a back cover positioned on the underside of the display panel, and a sealing member positioned between the back cover and the cover member, wherein the sealing member is configured to not have adhesive strength with the back cover and the cover member.

The detailed descriptions of other embodiments of the present invention are included in the specifications and drawings.

According to the embodiments of the present invention, the use of a non-adhesive sealing member in display devices is capable of preventing physical damage to the cover member and the back cover by avoiding adhesion to adjacent components.

The advantages according to the embodiments of the present invention are not limited to the aforesaid, and a variety of other advantages are included within the specification.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a plan view of a display device according to an embodiment of the present invention;

FIG. 2 is a cross-sectional view taken along the line I-I′ of FIG. 1;

FIG. 3 is a detailed cross-sectional view of a display panel according to an embodiment of the present invention;

FIG. 4 is a cross-sectional view of a display device according to another example of the present invention;

FIG. 5 is a cross-sectional view of a display device according to another example of the present invention;

FIG. 6 is a cross-sectional view of a display device according to another example of the present invention;

FIG. 7 is a cross-sectional view of a display device according to another example of the present invention;

FIG. 8 is a cross-sectional view of a display device according to another example of the present invention;

FIG. 9 is a cross-sectional view of a display device according to another example of the present invention;

FIG. 10 is a cross-sectional view of a display device according to another example of the present invention; and

FIG. 11 is a cross-sectional view of a display device according to another example of the present invention.

### DETAILED DESCRIPTIONS OF THE EMBODIMENTS

Advantages and features of the present invention and methods of accomplishing the same can be understood more readily by reference to the following detailed description of embodiments and the accompanying drawings. The present invention can, however, be embodied in many different forms and should not be construed as being limited to the exemplary embodiments set forth herein; rather, these exemplary embodiments are provided so that the present invention will be thorough and complete and will fully convey the concept of the invention to those skilled in the art, and the present invention will only be defined by the appended claims.

When it is mentioned that one device or layer is located or positioned on another device or layer, it can be understood that one device or layer is directly located on the other device or layer or that still other device(s) or layer(s) are interposed between the two devices or layers.

Throughout the specification, the same reference numerals refer to the same components. The shapes, sizes, ratios, angles, numbers and the like disclosed in the drawings to describe embodiments of the present invention are merely exemplary, and thus, the present invention is not limited thereto.

Although the terms “first”, “second”, and the like are used for describing various components, these components are not confined by these terms. These terms are merely used for distinguishing one component from the other components, and my not define any order or sequence. Accordingly, a first component mentioned earlier can also be a second component within the technical spirit of the present invention.

The various features of the embodiments of the present invention can combined or assembled together, either partially or entirely, in a technically diverse manner, and each embodiment can be independently implemented or in conjunction with related embodiments.

Hereinafter, exemplary embodiments of the present invention will be described in detail with reference to accompanying drawings. All the components of each display device according all embodiments of the present invention are operatively coupled and configured.

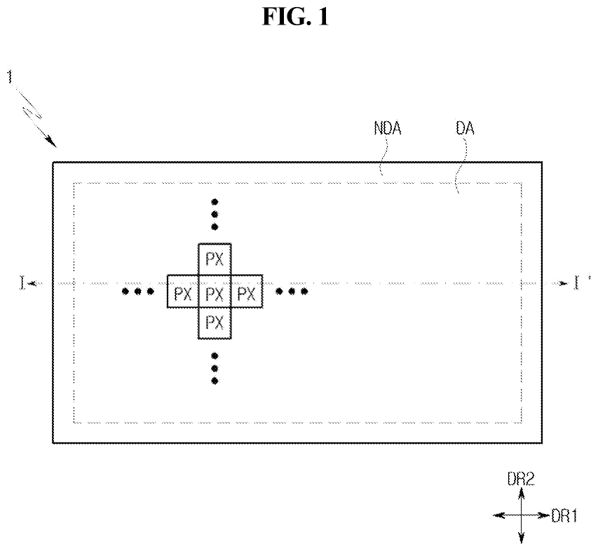

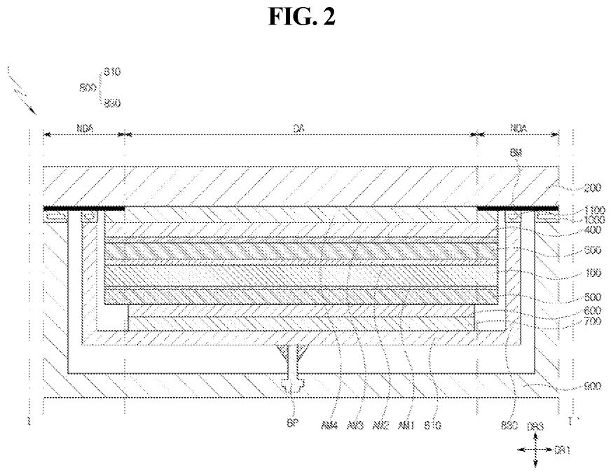

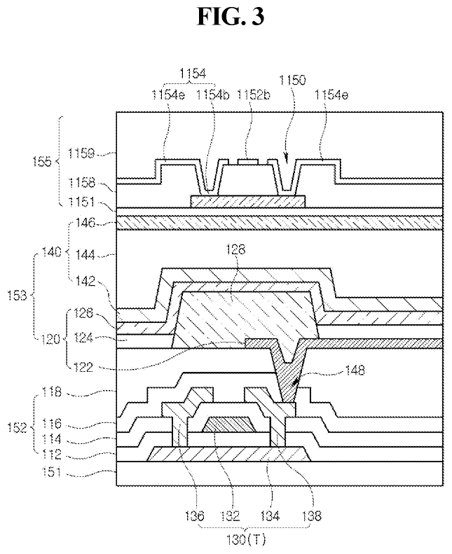

FIG. 1 is a plan view of a display device according to an embodiment of the present invention; FIG. 2 is a cross-sectional view taken along line I-I′ of FIG. 1. FIG. 3 is a detailed cross-sectional view of a display panel according to an embodiment of the present invention.

With reference to FIGS. 1 and 2, a display device 1 according to an embodiment of the present invention can refer to any electronic device that provides a display screen. Examples of the display device 1 can include mobile phones, smartphones, tablet PCs, electronic watches, smartwatches, watch phones, mobile communication terminals, electronic notebooks, electronic books (e-books), Portable Multimedia Players (PMPs), navigation devices, game consoles, digital cameras, televisions, laptops, monitors, advertising displays, and Internet of Things (IOT) devices that are equipped with a display screen. For example, the display device 1 according to an embodiment of the present invention can be, but not limited to, a display device for a vehicle.

The display device 1 can have a rectangular shape including elongated sides extended in a first direction DR1 and shorter sides extended in a second direction DR2. The corners where the elongated sides and shorter sides meet can be angular, but they are not limited to such and can have a curved shape. Without being limited to these examples, the planar shape of the display device 1 can also be a square, circular, elliptical, or other polygonal shape.

The display panel 1 can include a display area DA and a non-display area NDA surrounding or being adjacent to the display area DA. The display area DA can include a plurality of pixels PX and is capable of generating images. Meanwhile, the non-display area NDA may not generate images, and it is not limited to generating images.

As shown in FIG. 2, the display device 1 can include a display panel 100, a cover member 200 on the display panel 100, a polarizing member 300 between the display panel 100 and the cover member 200, a viewing angle control member 400 between the polarizing member 300 and the cover member 200, a support member 500 on the lower side of the display panel 100, a metal plate 600 below the support member 500, a guide holder 700 on the lower side of the metal plate 600, a core plate 800 on the lower side of the guide holder 700, and a back cover 900 on the lower side of the core plate 800.

The aforementioned display area DA and non-display area NDA are defined in the display panel 100.

With reference to FIG. 3, the display panel 100 includes a thin-film transistor array 152 and a light-emitting device array 153 stacked on a substrate 151 and a touch panel 155 positioned on the light-emitting device array 153. In addition to the touch panel 155, additional components for providing user authentication functionality (e.g., fingerprint recognition), multi-level pressure sensing functionality, tactile feedback functionality, and the like can be included on the light-emitting device array 153.

The thin-film transistor array 152 and the light-emitting device array 153 are composed of one or more thin-film transistors (TFTs) and light-emitting devices 120 connected to the thin-film transistors, respectively, defined in a matrix form for multiple sub-pixels within the display area AA of the substrate 151. A detailed description thereof is made with reference to FIG. 2.

The substrate 151 supports various components of the display panel 100. The substrate 151 can serve as the base substrate for the display panel 100.

For example, it can include flexible materials such as polyimide, which provides flexibility, or it can be made of a flexible glass material in the form of a thin film.

The substrate 151 can be formed of a transparent dielectric material such as glass, plastic, and the like. In the case of being made of plastic, the substrate 151 can be a plastic film or plastic substrate with a flexibility or a flexible substrate. For example, the substrate 151 can be in the form of a film and include one of a polyimide-based polymer, a polyester-based polymer, a silicone-based polymer, an acrylic-based polymer, a polyolefin-based polymer, and their copolymers, but the embodiments of this specification are not limited to thereto. Among these materials, polyimide is commonly used as a plastic substrate because it is suitable for high-temperature processes and is a material that can be coated.

The substrate (array substrate) can include various components and functional layers formed on the substrate 151, such as switching TFTs, driving TFTs connected to the switching TFTs, light-emitting devices connected to the driving TFTs, protective layers, and so on, but the embodiments of this specification are not limited thereto.

In some cases, a buffer layer can be positioned on the substrate 151. The buffer layer is a functional layer to protect thin-film transistors (TFTs) from impurities such as alkali ions that can be released from the substrate 151 or underlying layers. The buffer layer can be made of silicon oxide (SiOx), silicon nitride (SiNx), or a multilayer of these materials, but the embodiments of this specification are not limited thereto.

The thin-film transistor array 152 can include a thin-film transistor (TFT) 130 in which a gate electrode 132, a gate insulating layer 112, a semiconductor layer 134, an interlayer insulating layer 114, and source and drain electrodes 136 and 138 are sequentially arranged. The thin-film transistor (TFT) 130 can be included in one or more quantities for a plurality of sub-pixels provided in the display area AA on the substrate 151.

The arrangement order of the semiconductor layer 134 and the gate electrode 132 can be changed.

The semiconductor layer 134 is positioned on a specific region of the substrate 151 or the buffer layer. The semiconductor layer 134 can be made of polycrystalline silicon (p-Si), and in this case, a region can be doped with impurities. The semiconductor layer 134 can also be made of amorphous silicon (a-Si) and various organic semiconductor materials such as pentacene. Furthermore, the semiconductor layer 134 can also be made of an oxide material. The gate insulating layer 112 can be formed of inorganic insulating materials such as silicon oxide (SiOx) or silicon nitride (SiNx) and, as well, organic insulating materials. The gate electrode 132 can be formed of various conductive materials, such as magnesium (Mg), aluminum (Al), nickel (Ni), chromium (Cr), molybdenum (Mo), tungsten (W), gold (Au), or alloys thereof, but the embodiments of this specification are not limited thereto.

The first interlayer insulating layer 114 can be formed of inorganic insulating materials such as silicon oxide (SiOx) or silicon nitride (SiNx), and also be formed of organic insulating materials. The first interlayer insulating layer 114 can be selectively removed to form contact holes exposing the source and drain regions.

The source and drain electrodes 136 and 138 are formed as a single layer or multilayer of electrode material on the first interlayer insulating layer 114.

An inorganic protective film 116 and a planarization layer 118 can be positioned on the thin film transistor to cover the source and drain electrodes 136 and 138. The inorganic protective layer 116 and planarization layer 118 serve to protect the thin-film transistor and flatten its upper surface. The inorganic protective layer 116 can be formed of inorganic insulating films such as silicon nitride (SiNx) or silicon oxide (SiOx), but the embodiments of this specification are not limited thereto. The planarization layer 118 can be composed of an organic insulating film including benzocyclobutene (BCB), acrylic (Acryl), or the like, but the embodiments of the specification are not limited thereto. The inorganic protective film 116 and the planarization layer 118 can each be formed as a single layer, dual-layer, or multilayer, and one of the two layers can be omitted in some cases.

The thin-film transistor array 152 can be described as including the thin-film transistor 130 (TFT) provided in each sub-pixel on the substrate 151, along with the inorganic protective film 116 and the planarization layer 118.

A light-emitting device 120 connected to the thin film transistor (TFT) can be formed by sequentially arranging a first electrode 122, an light-emitting layer 124, and a second electrode 126. For example, the light-emitting device 120 can be composed of the first electrode 122 connected to the drain electrode 138 through the via hole 148 formed in the planarization layer 118 and the inorganic protective film 116, the light emitting layer 124 positioned on the first electrode 122, and the second electrode 126 positioned on the light-emitting layer 124.

When the display panel 100 is of a top emission type where the emission occurs upward through the second electrode 126, the first electrode 122 can include an opaque conductive material with high reflectivity. In this case, examples of the reflective conductive material can include silver (Ag), aluminum (Al), gold (Au), molybdenum (Mo), tungsten (W), chromium (Cr), or alloys thereof, but the embodiments of this specification are not limited thereto.

A bank 128 is formed in the area excluding the light-emitting area, opening up the light-emitting area. Accordingly, the bank 128 has a bank hole exposing the first electrode 122 corresponding to the light-emitting area. The bank 128 can be made of inorganic insulating materials such as silicon nitride (SiNx) and silicon oxide (SiOx) or organic insulating materials such as BCB, acrylic-based resins, or imide-based resins, but the embodiments of this specification are not limited thereto.

The light-emitting layer 124 is positioned on the first electrode 122 exposed by the bank 128. The light-emitting layer 124 can include a hole injection layer, a hole transport layer, an emissive layer, an electron transport layer, and an electron injection layer, but the embodiments of this specification are not limited thereto. In addition, the light-emitting layer 124 can be composed of a single emissive layer structure that emits a single light within a single stack, or a multi-stack structure including multiple stacks, each of which includes a single emissive layer of the same color. In such cases, adjacent sub-pixels can be arranged to emit different colors of light to display various colors. For example, sub-pixels with light-emitting layers in red, green, and blue can be arranged side by side or in a triangular pattern. In some cases, sub-pixels of white color can also be added to the arrangement.

In addition, the light-emitting layer 124 can be configured by stacking a plurality of stacks including emissive layers emitting different colors of light to express white. In the case of expressing white with a stacked structure, separate color filters can be additionally added to each sub-pixel. The embodiments of this specification are not limited thereto.

The second electrode 126 is positioned on the light-emitting layer 124. When the display panel 100 adopts a top emission structure, the second electrode 126 can be formed of a transparent conductive material such as indium tin oxide (ITO) or indium zinc oxide (IZO) or a semi-transparent metal or metal alloy such as MgAg to emit light generated in the light-emitting layer 124 upward through the second electrode 126.

In FIG. 3, the light-emitting device array 153 can have a configuration encompassing the structure in which the light-emitting device 120 including the first electrode 122, the light-emitting layer 124, and the second electrode 126 are stacked on the thin-film transistor array 152, and a capping layer on top of the second electrode 126. The capping layer serves to protect the light-emitting device 120 and assist in the extraction of light emitted from the second electrode 126.

The light-emitting device array 153 includes the encapsulation layer 140. The encapsulation layer 140 prevents the infiltration of oxygen and moisture from the outside to prevent oxidation of the emissive and electrode materials. Exposure of light-emitting device 120 to moisture or oxygen can cause pixel shrinkage or the formation of dark spots, reducing the light-emitting area. The encapsulation layer 140 is formed by alternately stacking inorganic layers 142 and 146 made of glass, metal, aluminum oxide (AlOx), or silicon (Si) materials and an organic layer 144 that serves as a buffer relieving the stress between layers due to the bending of the display panel 100 and enhances the flattening performance. Here, the organic layer 144 can be made of organic insulating materials such as acrylic resin, epoxy resin, polyimide, polyethylene, or silicon oxycarbide (SiOC), but the embodiments of this specification are not limited thereto. Here, the first and second inorganic layers 142 and 146 serve to block the penetration of moisture or oxygen, while the organic layer 144 flattens the surface of the first inorganic layer 142. The encapsulation layer 140 is composed of several thin film layers to increase the length and complexity of the path that moisture and oxygen must travel compared to a single layer, with the purpose of blocking the penetration of moisture and oxygen to the light-emitting device array 153.

A protective layer can be formed further between the light-emitting device 120 and the encapsulation layer 140 to protect the encapsulation layer 140 from being peeled off or affecting the uniformity during the manufacturing process of the encapsulation layer 140. In some cases, the encapsulation layer 140 is considered a component of the light-emitting device array 153 because of its essentiality for moisture-sensitive light-emitting device 120. In FIG. 2, the configuration representing the light-emitting device array 153 includes the encapsulation layer 140 and the light-emitting device 120.

The display panel 100 of this specification further includes a touch panel 155 on the light-emitting device array 153 to detect touch gestures from the viewer (user).

A touch buffer layer 1151 can be positioned on the encapsulation layer 140. The touch buffer layer 1151 can be positioned on the front side of both the display area AA and the non-display area NA, and it can extend to the pad area if necessary. The touch buffer layer 1151 can be an insulating layer but is not limited thereto.

The touch buffer layer 1151 can be composed of at least one of inorganic materials such as silicon nitride (SiNx), silicon oxide (SiOx), or aluminum oxide (AlyOz), etc., but is not limited thereto.

A first touch electrode 1154 can be arranged on the touch buffer layer 1151.

The touch panel 155 can include the first touch electrode 1154 and the second touch electrode (in the same layer as 1152b) intersecting each other, allowing one electrode to receive an applied voltage signal and the other to sense the voltage signal. The first touch electrode 1154 and the second touch electrode are each provided on the touch insulating layer 1158 in a polygonal or circular pattern known as the main pattern 1154e, which are separated from each other to connect adjacent main patterns, first and second bridge patterns 1154b and 1152b being located in different layers. In the drawing, an example where the first bridge pattern 1154b is directly positioned above the light-emitting device array 153, but embodiments are not limited thereto and can additionally provide an insulating layer or insulating material on the light-emitting device array 153 and equip the first bridge pattern 1154b on its upper part. The second bridge pattern 1152b is located in the same layer as the main pattern of the second touch electrode, i.e., the touch insulation layer 1158, and can be formed as an integral structure. In this case, the main pattern 1154e of the first touch electrode 1154 is spaced apart from the second touch electrode to be electrically separated. The embodiments of this specification are not limited thereto.

In order to apply and sense voltage signals on the touch panel 155, a flexible film can come into contact with the touch pads located on one side of the first touch electrode 1154 and the second touch electrode (the same layer as 1152b). For example, the touch pads can be located on the same layer as the first bridge pattern 1154b, i.e., on the upper side of the light-emitting device array 153. The embodiments of this specification are not limited thereto.

A second planarization layer 1559 can be arranged on the second touch electrode (the same layer as 1152b) and the first bridge pattern 1154b.

The second planarization layer 1159 can serve to cover and flatten the second touch electrode (the same layer as 1152b), the first bridge pattern 1154b, and the touch insulating layer 1158. Additionally, the second planarization layer 1159 can be composed of one or more of organic insulating materials such as BenzoCycloButene (BCB), acrylic resin, epoxy resin, phenolic resin, polyamide resin, or polyimide resin, but is not limited thereto.

With reference back to FIG. 2, a polarizing member 300 can be positioned on the display panel 100. The polarizing member 300 can include a first phase delay layer, a second phase delay layer on the first phase delay layer, and a polarizing layer on the second phase delay layer. Since the polarizing member 300 is widely known in the art, detailed description thereof will be omitted.

The polarizing member 300 can be bonded to the display panel 100 via a second adhesive member AM2. The second adhesive member AM2 can include optical clear adhesive (OCA) or optical clear resin (OCR), but is not limited thereto. The materials of the subsequent third and fourth adhesive members AM3 and AM4 can also include any of the materials mentioned as examples for the second adhesive member AM2. The first adhesive member AM1 can include at least one of the materials mentioned as examples for the second adhesive member AM2, or include pressure-sensitive adhesive (PSA).

A viewing angle control member 400 can be positioned on the polarizing member 300. The viewing angle control member 400 can include a plurality of louvers extended in a predetermined direction and a light transmissive layer surrounding the louvers. The louvers can be arranged to be spaced apart from each other in the direction perpendicular to the predetermined direction to limit predetermined viewing angles of the light generated from the display panel 100.

The viewing angle control member 400 can be attached to the polarizing member 300 via a third adhesive member AM3.

A cover member 200 can be positioned on the viewing angle control member 400. The cover member 200 can include glass or plastic materials. The cover member 200 maybe positioned on the top of the display device 1, serving to protect the underlying components.

The cover member 200 can have a shape that extends further outward than the sides of the display panel 100, polarizing member 200, and viewing angle control member 400. The lower surface of the cover member 200 can have a light-blocking pattern BM formed thereon. The light-blocking pattern BM is placed on the non-display area NDA and contains black pigments or black dyes to prevent the non-display area NDA from being visible from the outside.

The third adhesive member AM3 can directly contact the lower surface and sides of the light-blocking pattern BM.

A support member 500 can be placed on the underside of the display panel 100. The support member 500 can be positioned on the underside of the display panel 100 to provide support for the display panel 100. The support member 500 can include materials capable of supporting the substrate 110. For example, the support member 500 can include materials such as polyethylene terephthalate (PET), polyimide (PI), or polycarbonate (PC), but is not limited thereto.

The support member 500 can be attached to the lower surface of the display panel 100 via the first adhesive member AM1. Since the light generated from the display panel 100 propagates in the upward direction, the first adhesive member AM1 does not necessarily need to be a transparent adhesive compared to the second to fourth adhesive members AM2 to AM4. The transparency of the first adhesive member AM1 can be lower than that of the second to fourth adhesive members AM2 to AM4, but it is not limited to that. A metal plate 600 can be positioned on the underside of the support member 500. The metal plate 600 can be attached to the underside of the support member 500 via an adhesive member. For example, the metal plate 600 can include stainless steel. For example, stainless steel can include at least one of iron, chromium, carbon, nickel, silicon, manganese, molybdenum, and alloys thereof.

The planar area of the metal plate 600 can be smaller than the planar area of the display panel 100. For example, the side of the metal plate 600 can be positioned inward relative to the side of the display panel 100, but it is not limited to that configuration. The metal plate 600 can serve to dissipate heat generated from the display panel 100 to the outside.

The guide holder 700 can be positioned on the underside of the metal plate 600. Components such as a printed circuit board (PCB) electrically connected to the display panel 100 can be mounted on the guide holder 700. The guide holder 700 can be attached to the underside of the metal plate 600 via an adhesive member.

The core plate 800 can be positioned on the underside of the guide holder 700. The core plate 800 can include a core supporting portion 810 that overlaps with the display panel 100 and a core side portion 830 that is bent and extends in the thickness direction from the core supporting portion 810. The lateral side of the core supporting portion 810 can be positioned outward from the lateral side of the display panel 100. The planar area of the core supporting portion 810 can be larger than the planar area of the display panel 100. The core side portion 830 extends in the thickness direction (e.g., the third direction, DR3) from the lateral side of the core supporting portion 810, which is positioned outward compared to the lateral side of the display panel 100, to cover the side of the display panel 100.

The core plate 800 is positioned beneath the metal plate 600, providing support to the display panel 100 from underneath while covering the side of the display panel 100, allowing for protection of the display panel 100 from external factors. The material of the core plate 800 is not limited to any specific options but can include stainless steel, alloys containing magnesium, or plastics incorporating black pigments or black dyes, such as polycarbonate (PC).

A back cover 900 can be positioned on the underside of the guide holder 800. The back cover 900 can include a back cover supporting portion that overlaps with the display panel 100 and a back cover side portion that is bent and extends in the thickness direction from the back cover supporting portion. The lateral side of the back cover supporting portion can be positioned outward from the side of the display panel 100. The lateral side of the back cover supporting portion can be positioned outward from the lateral side of the core supporting portion. The planar area of the back cover supporting portion can be larger than the planar area of the display panel 100 and the core supporting portion 810. The back cover side portion can cover the sides of both the core side portion 830 and the display panel 100.

The back cover 900 can be positioned at the bottommost and outermost part of the display device 1 and be connected to the cover member 200, serving as a component necessary for the assembly of the display device 1.

The material of the back cover 900 is not limited to any specific options but can include stainless steel, alloys containing magnesium, or plastics incorporating black pigments or black dyes, such as polycarbonate (PC).

Meanwhile, a first sealing member 1000 can be positioned between the back cover 900 and the cover member 200. The first sealing member 1000 can be positioned in the non-display area NDA. The first sealing member 1000 can be interposed between the back cover side portion of the back cover 900 and the light-blocking pattern BM. The first sealing member 1000 can include molding member or foam member. The molding member can be made of rubber material or silicon material, while the foam member can include polyethylene, acrylic, or polyurethane. The first sealing member 1000 can serve as a sealing material without the need to bond the back cover 900 and cover member 200 (or light-blocking pattern BM) unlike the existing double-sided tape or adhesive resin used for bonding the back cover 900 and cover member 200 (or light-blocking pattern BM). In contrast to traditional bonding materials, the first sealing member 1000 can be easily removed from between the back cover 900 and the cover member 200, facilitating straightforward realignment of the back cover 900 with the cover member 200, even in cases where misalignment occurs during the securing process.

Furthermore, unlike conventional bonding materials with a fixed thickness that are ineffective when the set structure of the display device 1 is changed, the display device 1, as designed according to an embodiment, offers the advantage of effectively accommodating changes in the set structure by allowing for thickness adjustment of the first sealing member 1000 applied between the cover member and the back cover. In this specification, the adjustability of the first sealing member 1000 refers to the ability to control its thickness and, thus, assuming that the first sealing member 1000 having an initial thickness (e.g., first thickness) is placed between the back cover 900 and the cover member 200, by compressing the first sealing member 1000 to a distance (e.g., first distance) desired between the back cover 900 and the cover member 200 (or light-blocking pattern BM), the first sealing member 1000 can be adjusted to a thickness corresponding to the first distance. The first sealing member 1000 can be a flexible material that allows for thickness adjustment depending on the first distance variation.

According to an embodiment of the present invention, the display device 1 can further include a second sealing member 1100. The second sealing member 1100 can be positioned between the core side portion 830 and the cover member 200 (or light-blocking pattern BM). The second sealing member 1100 can be interposed between the core side portion 830 and the light-blocking pattern BM. The second sealing member 1100 can include molding member or foam member. The molding member can be made of rubber material or silicone material, while the foam member can include polyethylene, acrylic, or polyurethane.

The core plate 800 can be fastened to the back cover 900 via a fixing member BP. The fixing member BP can be in the form of a screw, but is not limited thereto.

Hereinafter, a description is made of the display device 1 according to alternative examples or embodiments of the present invention. The features of the display device 1 can be applied to or are included in each display device of various examples of the present invention.

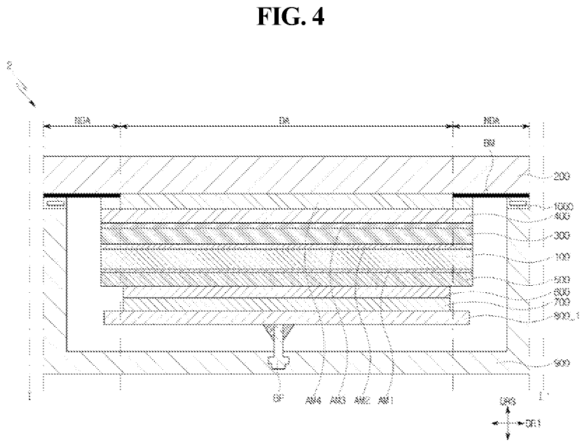

FIG. 4 is a cross-sectional view of a display device according to another example of the present invention.

With reference to FIG. 4, a display device 2 of this embodiment differs from the display device 1 in FIG. 2 in that the core plate 800_1 does not include a core side portion. Furthermore, due to the absence of a core side portion, the second sealing member 1100 depicted in FIG. 2 is omitted in the display device 2, making it different from the display device 1 of FIG. 2.

The additional description that has already been made with reference to FIG. 2 will be omitted.

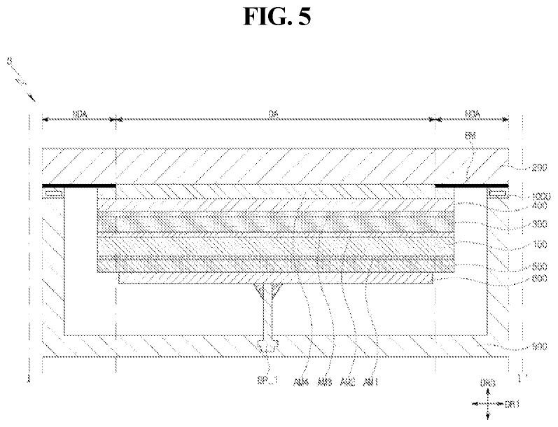

FIG. 5 is a cross-sectional view of a display device according to another example of the present invention;

With reference to 5, a display device 3 according to this embodiment differs from the display device 2 of FIG. 4 in that the guide holder 700 and the core plate 800_1 are not included and the metal plate 600 fastened to the back cover 900 via a fixing member BP_1.

The additional description that has already been made with reference to FIGS. 2 and 4 will be omitted.

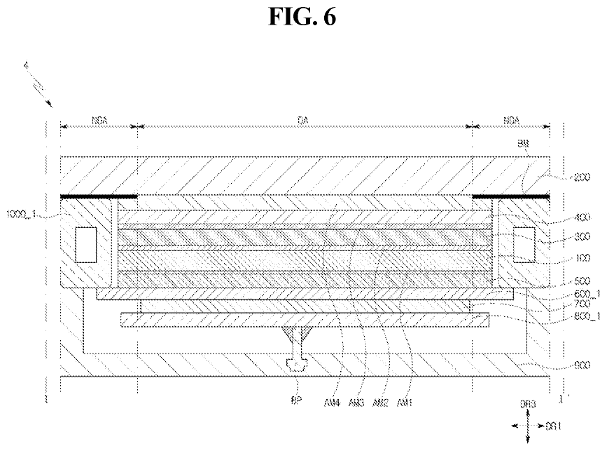

FIG. 6 is a cross-sectional view of a display device according to another example of the present invention;

With reference to FIG. 6, a display device 4 according to this embodiment differs from the display device 2 of FIG. 4 in that the lateral side of the metal plate 600_1 extends outward from the lateral side of the display panel 100.

The metal plate 600_1 can include an overlapping portion that overlaps with the display panel 100 and a protruding portion protruding outward from the side of the display panel 100.

The first sealing member 1000_1 can be placed between the protruding portion of the metal plate 600_1 and the cover member 200. For example, the first sealing member 1000_1 can be positioned between the back cover side portion of the back cover 900 and the cover member 200, as well as between the protruding portion of the metal plate 600_1 and the cover member 200.

The additional description that has already been made with reference to FIG. 4 will be omitted.

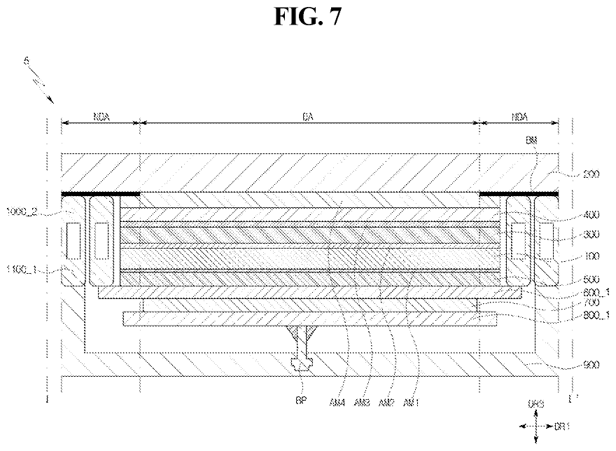

FIG. 7 is a cross-sectional view of a display device according to another example of the present invention.

With reference to FIG. 7a the display device 5 according to this embodiment differs from the display device 4 of FIG. 6 in that the first sealing member 1000_2 is placed between the back cover side portion and the cover member 200, and the second sealing member 1100_1 is placed between the protruding portion of the metal plate 600_1 and the cover member 200. The first sealing member 1000_2 and the second sealing member 1100_1 can be spaced apart from each other in the first direction DR1.

The additional description that has already been made with reference to FIG. 6 will be omitted.

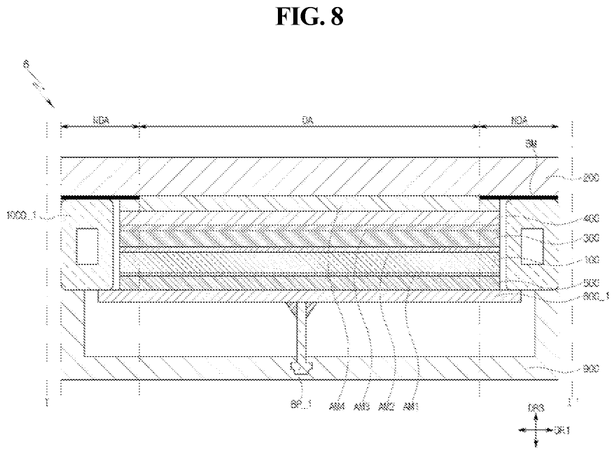

FIG. 8 is a cross-sectional view of a display device according to another example of the present invention.

With reference to FIG. 8, a display device 6 according to this embodiment differs from the display device 4 of FIG. 6 in that the guide holder 700 and the core plate 800_1 are omitted. In FIG. 8, the metal plate 600_1 of the display device 6 can be secured to the back cover 900 via a fixing member BP_1.

The additional description that has already been made with reference to FIG. 6 will be omitted.

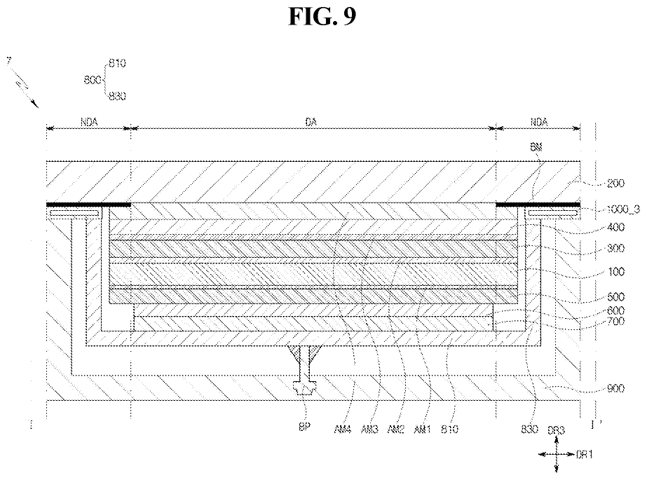

FIG. 9 is a cross-sectional view of a display device according to another example of the present invention.

With reference to FIG. 9, a display device 7 of this embodiment differs from the display device 1 of FIG. 2 in that the first sealing member 1000 and the second sealing member 1100 are formed integrally.

In more detail, the first sealing member 1000_3 can be integrally formed to be positioned between the back cover side portion of the back cover 900 and the cover member 200 and between the core side portion 830 of the core plate 800 and the cover member 200.

The additional description that has already been made with reference to FIG. 2 will be omitted.

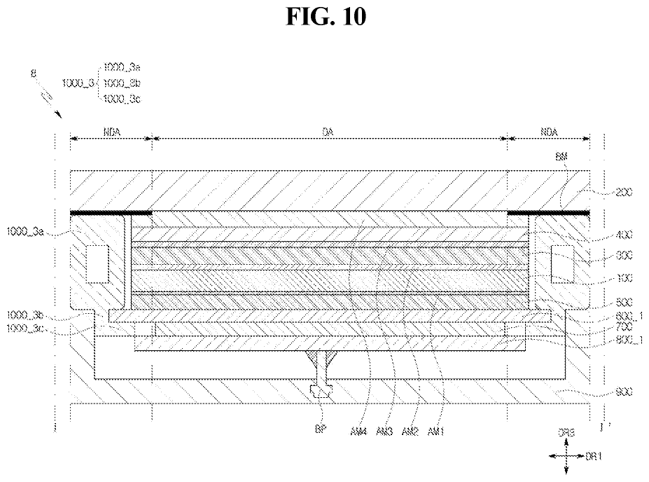

FIG. 10 is a cross-sectional view of a display device according to another example of the present invention.

With reference to FIG. 10, a display device 8 of this embodiment differs from the display device 4 of FIG. 6 in that the first sealing member 1000_4 can be additionally positioned on the side and bottom surfaces of the metal plate 600_1.

In more detail, the first sealing member 1000_4 can include a first portion 1000_4a positioned between the back cover side portion of the back cover 900 and the cover member 200, a second portion 1000_4b connected to the first portion 1000_4a and positioned on the lateral side of the metal plate 600_1, and a third portion 1000_4c connected to the second portion 1000_4b and positioned on the bottom surface of the metal plate 600_1. The first portion 1000_4a, the second portion 1000_4b, and the third portion 1000_4c, can be formed as an integrated member.

The first portion 1000_4a can be positioned and shaped similarly to the first sealing member 1000_1 in FIG. 6, the second portion 1000_4b can be position between the back cover side portion of the back cover 900 and the side of the metal plate 600_1, and the third portion 1000_4c can be positioned on the bottom surface of the metal plate 600_1. The first sealing member 1000_4 is formed to contact the top, side, and bottom surfaces of the metal plate 600_1, increasing the contact area between the first sealing member 1000_4 and the metal plate 600_1 compared to the first sealing member 1000_1 in FIG. 6, and the structure of clamping the metal plate 600_1 enhances the stability of the display device 8.

The additional description that has already been made with reference to FIG. 6 will be omitted.

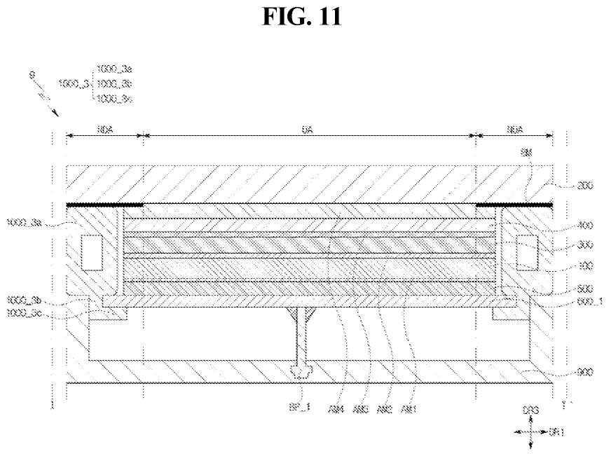

FIG. 11 is a cross-sectional view of a display device according to another example of the present invention.

With reference to FIG. 11, a display device 9 of this embodiment differs from the display device 8 of FIG. 10 in that the guide holder 700 and the core plate 800_1 are omitted. The metal plate 600_1 can be secured to the back cover 900 via a fixing member BP_1.

The additional description that has already been made with reference to FIG. 10 will be omitted.

Although embodiments of this invention have been described above with reference to the accompanying drawings, it will be understood by those skilled in the art that this invention can be implemented without departing the technical concept of this invention. Therefore, it should be understood that the embodiments described above are exemplary and not limited in all respects.

What is claimed is:

1. A display device comprising:
a display panel;
a cover member positioned on the display panel;
a back cover positioned on an underside of the display panel; and
a first sealing member positioned between the back cover and the cover member,
wherein the first sealing member comprises a molding member or foam member.

2. The display device of claim 1, wherein each of the cover member and the back cover extends outward from a side of the display panel,
the display panel comprises a display area including a plurality of pixels and a non-display area adjacent to the display area, and
the first sealing member is positioned on the non-display area.

3. The display device of claim 2, wherein the back cover comprises a back cover supporting portion and a back cover side portion bent and extending in a thickness direction from the back cover supporting member, and the first sealing member positioned between the back cover side portion and the cover member.

4. The display device of claim 3, further comprising:
a light-blocking pattern positioned on a lower surface of the cover member in the non-display area,
wherein the first sealing member is interposed between the back cover side portion and the light-blocking pattern.

5. The display device of claim 4, further comprising:
a core plate positioned between the display panel and the back cover.

6. The display device of claim 5, further comprising:
a second sealing member positioned between the core plate and the cover member,
wherein the core plate comprises a core supporting portion and a core side portion bent and extending in the thickness direction from the core supporting portion.

7. The display device of claim 6, wherein the second sealing member is positioned between the core side portion and the cover member, and the second sealing member is interposed, in the non-display area, between the core side portion and the light-blocking pattern.

8. The display device of claim 6, wherein the first sealing member is interposed between the core side portion and the light-blocking pattern.

9. The display device of claim 5, wherein the core plate is fastened to the back cover.

10. The display device of claim 4, further comprising:
a metal plate positioned between the display panel and the back cover.

11. The display device of claim 10, wherein the metal plate is fastened to the back cover.

12. The display device of claim 10, further comprising:
a core plate positioned between the metal plate and the back cover,
wherein the core plate is fastened to the back cover.

13. The display device of claim 10, wherein the metal plate extends outward from the side of the display panel.

14. The display device of claim 13, wherein the first sealing member is positioned between the metal plate and the cover member, and is positioned on side and bottom surfaces of the metal plate.

15. The display device of claim 13, further comprising:
a second sealing member positioned between the metal plate and the cover member.

16. The display device of claim 1, wherein the molding member of the first sealing member comprises a rubber material or silicon material, or
the foam member of the first sealing member comprises polyethylene, acrylic, or polyurethane.

17. A display device comprising:
a display panel;
a cover member positioned on the display panel;
a back cover positioned on an underside of the display panel; and
a sealing member positioned between the back cover and the cover member,
wherein the sealing member is configured to not have adhesive strength with respect to the back cover and the cover member.

18. The display device of claim 17, wherein the sealing member comprises a molding member or a foam member.

19. The display device of claim 18, wherein each of the cover member and the back cover extends outward from a side of the display panel,
the display panel comprises a display area including a plurality of pixels and a non-display area adjacent to the display area, and
the sealing member is positioned on the non-display area.

20. The display device of claim 19, further comprising:
a light-blocking pattern positioned on a lower surface of the cover member in the non-display area,
wherein the back cover comprises a back cover supporting portion and a back cover side portion bent and extending in a thickness direction from the back cover supporting member, and the sealing member positioned between the back cover side portion and the cover member and interposed between the back cover side portion and the light-blocking pattern.
